(19) United States
(12) Patent Application Publication
(10) Pub. No.: US 2023/0422456 A1
(43) Pub. Date: Dec. 28, 2023

(54) CONDUCTIVE POLYMERIC MATERIAL AND CABLE THEREWITH

(71) Applicant: Swift Bridge Technologies (M) Sdn Bhd, Penang (MY)

(72) Inventor: Dalibor Jan Smejtek, Portland, OR (US)

(21) Appl. No.: 18/340,223

(22) Filed: Jun. 23, 2023

Related U.S. Application Data
(60) Provisional application No. 63/356,007, filed on Jun. 27, 2022.

(51) Int. Cl. H05K 9/00; H01B 1/22

(52) U.S. Cl. CPC H05K 9/0098; H01B 1/22

(57) ABSTRACT

A cable includes an inner conductor, a dielectric layer extending around the inner conductor, and a polymeric material extending around the dielectric layer. The polymeric material includes a polymer core comprising opposite first and second sides. The polymer core includes a pore that extends through the first and second sides of the polymer core such that the polymer core is porous. The polymeric material includes first and second metallic layers extending on the first and second sides, respectively, of the polymer core. The polymeric material includes a metallic link extending through the pore from the first metallic layer to the second metallic layer such that the metallic link provides an electrically conductive path between the first and second metallic layers.

### BACKGROUND

Some known electrical cables are electrically shielded by braiding a wire mesh or serving wire around a core of the cable. The shielding is intended to minimize leakage of radio-frequency interference (RFI) and prevent electromagnetic interference (EMI) disturbances from distorting signals carried by the cable. However, gaps formed during braiding of the wire mesh or serving wire around the cable core and/or a looseness of the resulting braid may still cause some RFI leakage and/or signal distortion.

### SUMMARY

In one aspect, a cable includes an inner conductor, a dielectric layer extending around the inner conductor, and a polymeric material extending around the dielectric layer. The polymeric material includes a polymer core comprising opposite first and second sides. The polymer core includes a pore that extends through the first and second sides of the polymer core such that the polymer core is porous. The polymeric material includes first and second metallic layers extending on the first and second sides, respectively, of the polymer core. The polymeric material includes a metallic link extending through the pore from the first metallic layer to the second metallic layer such that the metallic link provides an electrically conductive path between the first and second metallic layers.

In another aspect, a cable includes an inner conductor, a dielectric layer extending around the inner conductor; and an outer conductor extending around the dielectric layer. The outer conductor includes a polymeric material that includes a polymer core having opposite first and second sides. The polymer core extends a thickness from the first side to the second side. The polymer core is porous with pores that extend through the thickness of the polymer core. The polymeric material includes first and second metallic layers extending on the first and second sides, respectively, of the polymer core. The polymeric material includes internal metallic structures extending within the pores, wherein the internal metallic structures conductively bridge the first and second metallic layers together.

In another aspect, a cable includes an inner conductor, a dielectric layer extending around the inner conductor, and an outer conductor extending around the dielectric layer. The outer conductor includes a polymeric material that includes a polymer core having opposite first and second sides. The polymer core is porous with pores that extend through the first and second sides of the polymer core. The polymeric material includes first and second metallic layers extending on the first and second sides, respectively, of the polymer core. The polymeric material includes internal metallic layers extending within the pores and configured such that the polymeric material is electrically conductive through a thickness of the polymeric material.

### BRIEF DESCRIPTION OF THE DRAWINGS

FIG. 1 is an isometric schematic view of a segment of a polymeric material according to an implementation.

FIG. 2 is a cross-sectional schematic view of the polymeric material shown in FIG. 1 according to an implementation.

FIG. 3 is an isometric view illustrating an exemplary microstructure of a polymer core of a polymeric material according to an implementation.

FIG. 4 is an isometric schematic view of a segment of a polymeric material according to an implementation.

FIG. 5 is an isometric schematic view of a segment of a polymeric material according to an implementation.

FIG. 6 is a cross-sectional schematic view of the polymeric material shown in FIG. 5 according to an implementation.

FIG. 7 includes isometric schematic views illustrating one example of fabrication of a polymeric material according to an implementation.

FIG. 8 is a flow chart illustrating a method for fabricating a polymeric material according to an implementation.

FIG. 9 is a partially broken-away elevational view of an electrical cable according to an implementation.

FIG. 10 is a cross-sectional view of the electrical cable shown in FIG. 9 according to an implementation.

FIG. 11 is a cross-sectional view of an electrical cable according to an implementation.

FIG. 12 is a cross-sectional view of an electrical cable according to an implementation.

FIG. 13 is a cross-sectional view of an electrical cable according to an implementation.

FIG. 14 is a cross-sectional view of an electrical cable according to an implementation.

FIG. 15 is a flow chart illustrating a method for assembling an electrical cable according to an implementation.

FIG. 16 illustrates an exemplary microstructure of a polymer core of a polymeric material according to an example.

FIG. 17 is an enlarged view of the polymer core shown in FIG. 16.

FIG. 18 illustrates the microstructure of the polymeric material shown in FIGS. 16 and 17 after a copper layer has been formed on the polymer core according to the example.

FIG. 19 is a plan view illustrating a surface of the copper layer of the polymeric material shown in FIG. 18 according to the example.

FIG. 20 illustrates the microstructure of the polymeric material shown in FIG. 18 after a silver layer has been formed thereon according to the example.

FIG. 21 is a plan view illustrating a surface of the silver layer of the polymeric material shown in FIG. 20 according to the example.

FIG. 22 illustrates an exemplary microstructure of a polymeric material according to another example.

FIG. 23 is a plan view illustrating a surface of a copper layer of the polymeric material shown in FIG. 22 according to the example.

### DETAILED DESCRIPTION

The foregoing summary, as well as the following detailed description of certain implementations will be better understood when read in conjunction with the appended drawings. While various spatial and directional terms, such as “top,” “bottom,” “upper,” “lower,” “vertical,” and/or the like are used to describe implementations of the present application, it is understood that such terms are merely used with respect to the orientations shown in the drawings. The orientations can be inverted, rotated, or otherwise changed, such that a top side becomes a bottom side if the structure is flipped 180°, becomes a left side or a right side if the structure is pivoted 90°, etc.

Technological advancements in electronics and signal transmission have caused signals to travel at higher and higher frequencies, thereby imposing new requirements upon wire and cable products. Some electrical cables are electrically shielded by braiding a wire mesh or serving wire around a core of the cable. The intent of the shielding is to prevent leakage of radio-frequency interference (RFI) from the cable and prevent electromagnetic interference (EMI) disturbances from distorting the signal. However, gaps created by virtue of the braid application process and/or a looseness of the resulting braid may still enable RFI leakage and/or signal distortion from EMI disturbances. Accordingly, some cables include a flat wire or a metal foil that is helically wound around the cable core. Adjacent windings of the wire or foil overlap each other such that very few, if any, gaps remain in the shielding along the length of the cable. However, the processes for applying (e.g., wrapping, etc.) the flat wire or metal foil around the cable core are challenging, inconsistent, and include variation, which results in, for example, inconsistencies in attenuation behavior and transmission losses (e.g., particularly for coaxial and twinaxial cables) and/or reflective losses and instability in the phase and/or time delay as the cable is moved and/or flexed. Moreover, as cables transmit signals at higher and higher frequencies, the diameter of the cables must be reduced. As the diameters are reduced to carry signals at frequencies higher than 70 GHz, for example, the challenges utilizing the current state of art (e.g., using flat wire and metal foils, etc.) are amplified.

Implementations described and/or illustrated herein attempt to resolve, reduce, and/or the like the aforementioned challenges, for example by creating an electrically conductive polymeric material using a porous polymer core that has been metallized such that the resulting polymeric material is electrically conductive through the thickness thereof. For example, certain implementations provide a polymeric material the includes a polymer core having opposite first and second sides. The polymer core includes a pore that extends through the first and second sides of the polymer core such that the polymer core is porous. The polymeric material includes a first metallic layer extending on the first side of the polymer core and a second metallic layer extending on the second side of the polymer core. In some implementations, the polymeric material includes a metallic link extending through the pore from the first metallic layer to the second metallic layer such that the metallic link provides an electrically conductive path between the first and second metallic layers. In some implementations, the polymeric material includes an internal metallic structure extending within the pore, wherein the internal metallic structure conductively bridges the first and second metallic layers together. In some implementations, the polymeric material includes an internal metallic layer extending within the pore and configured such that the polymeric material is electrically conductive through a thickness of the polymeric material.

Certain implementations provide polymeric materials that operate in an unconventional manner to provide improved electrical performance of polymer materials (e.g., improved electrical conductivity, improved electrical shielding capability, reduced unwanted capacitive behavior, etc.). For example, certain implementations provide polymeric materials that operate in an unconventional manner to provide improved electrical shielding materials. For example, the polymeric materials disclosed herein are less challenging to apply (e.g., wrap, etc.) over a cable core as compared to flat wire or metal foil, especially as the diameter of the cable core is reduced. For example, the polymeric materials disclosed herein may be applied around cable cores utilizing conventional (e.g., standard, etc.) dielectric tape wrapping equipment, thereby reducing the complexity and challenges of the wrapping process (e.g., a helical wrapping process, an axial wrapping process, etc.). The polymeric materials disclosed herein reduce or eliminate the challenges, inconsistencies, and variations of applying the flat wire or metal foil over the cable core, thereby resulting in improved electrical shielding (e.g., more effective shielding at relatively high frequencies, etc.). For example, the application of the polymeric materials over a cable core reduces or eliminates inconsistencies in attenuation behavior and transmission losses (e.g., particularly for coaxial and twin-axial cables) and/or reflective losses and instability in the phase and/or time delay as the cable is moved and/or flexed (e.g., as compared to cables including a wrapped flat wire or metal foil, etc.). Accordingly, incorporation of the polymeric materials disclosed herein within an electrical cable as an electrical shielding component results in improved signal propagation characteristics of the cable, especially at relatively high frequencies, while maintaining a relatively high flexibility and less distortion of the signal with bending (e.g., as compared to at least some known electrical cables, etc.). In certain implementations, the polymeric materials disclosed herein are used in combination with a conventional braided shield (e.g., a wire mesh or serving wire, etc.) that provides tensile strength to the resulting cable construction.

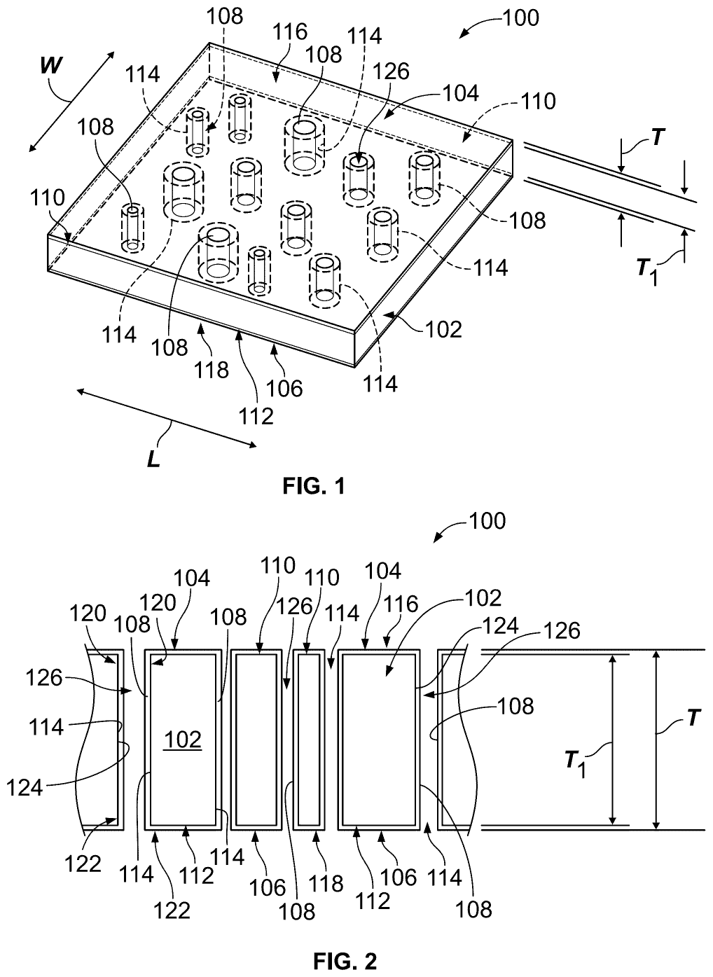

With references now to the figures, isometric and cross-sectional views of a polymeric material 100 are provided in FIGS. 1 and 2, respectively. The polymeric material 100 includes a polymer core 102, metallic layers 104 and 106, and metallic links 108. As will be described in more detail below, the metallic links 108 provide electrically conductive paths between the metallic layers 104 and 106, for example such that the polymeric material 100 is electrically conductive through a thickness T of the polymeric material 100. The polymer core 102 includes opposite sides 110 and 112. The polymer core 102 extends a thickness T₁ from the side 110 to the side 112, and vice versa. In other words, the polymer core 102 extends the thickness T₁ between the sides 110 and 112. Each of the metallic layers 104 and 106 may be referred to herein as a “first” metallic layer and/or a “second” metallic layer. Each of the sides 110 and 112 may be referred to herein as a “first” side and/or a “second” side.

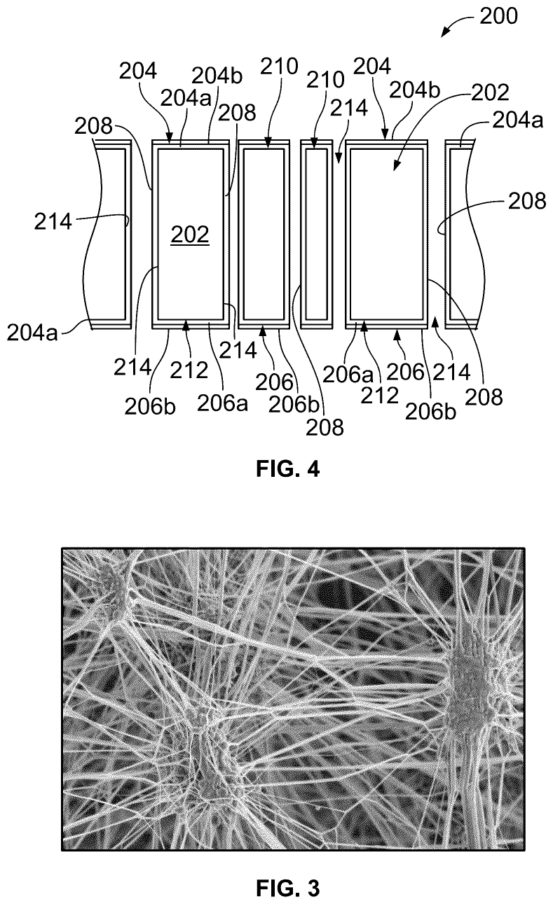

The polymer core 102 is porous. For example, the polymer core 102 has a porous structure that includes pores 114 that extend through the thickness T₁ of the polymer core 102. In other words, the pores 114 extend through the sides 110 and 112, and therebetween, of the polymer core 102. In some implementations, the polymer core 102 is nanoporous and/or microporous, for example having a microstructure wherein the pores 114 are micropores (e.g., have a size equal to or less than approximately 2 nanometers, etc.). The pores 114 illustrated herein (e.g., in FIGS. 1 and 2, etc.) are meant only as exemplary schematic (e.g., simplified, etc.) representations of the pores 114. It should be understood that the geometry of the pores 114 of the polymer core 102 may be more complex than shown herein. For example, the porous structure of the polymer core 102 may not be represented by individual concentric pores 114. For example, pores 114 may intersect each other and/or form a network of interconnected chambers within the thickness T₁ of the polymer core 102. Moreover, the size of the pores disclosed herein may be exaggerated in the figures for clarity. FIG. 3 illustrates one non-limiting example of a microstructure of the polymer core 102 that includes pores that intersect each other and form a network of interconnected chambers within the thickness of the polymer core 102.

In some implementations, the porosity of the polymer core 102 is selected to provide a configuration (e.g., size, shape, quantity, density, pattern, etc.) of the pores 114 that facilitates providing the polymeric material 100 with a predetermined level of electrical conductivity (e.g., by increasing the size, shape, and/or number of the metallic links 108, etc.). In some implementations, the porosity of the polymer core 102 is selected to facilitate fabrication (e.g., manufacture, creation, forming, etc.) of the polymeric material 100 (e.g., by reducing the difficulty of installing the metallic links 108 within the pores 114, etc.).

The predetermined porosity of the polymer core 102 may be selected, for example, via: material(s) selection; treatment of one or more selected materials (e.g., stretching, foaming, expanding, cross-linking, etc.); fabrication parameters (e.g., processes, operations, variables, conditions, etc.), for example parameters at which a material is stretched, foamed, expanded, and/or the like, etc.; and/or the like. For example, one or more various parameters of the polymer core 102 and/or the fabrication thereof may be selected to increase (e.g., maximize, increase to below a level at which the polymer core 102 and/or the polymeric material 100 loses mechanical structural integrity, etc.) the porosity of the polymer core 102. For example, the parameters at which the polymer core 102 is fabricated may affect the configuration (e.g., size, shape, quantity, density, pattern, etc.) of the pores 114 in the polymer core 102 (e.g., the temperature at which a stretching, foaming, expanding, and/or the like operation is performed on the polymer core 102 may affect the configuration of the pores 114 of the polymer core 102, etc.).

In some implementations, the polymer core 102 has a porosity of at least approximately 40%, approximately 50% (i.e., in some implementations the polymer core 102 is configured to include approximately 50% air), greater than approximately 50%, at least approximately 60%, and/or the like. The polymer core 102 may include any number of the pores 114, any density of the pores 114, and each pore 114 may have any size and/or shape, that provides the polymer core 102 with the predetermined porosity.

The polymer core 102 is comprised of any suitable materials that enable the polymer core 102 and/or the polymeric material 100 to function, for example as described and/or illustrated herein, such as, but not limited to, polypropylene, polytetrafluoroethylene (PTFE), polysulfone, cellulose-acetate, an expanded polymer, a foamed polymer, a stretched polymer, a linearly-stretched polymer, a porous polyester film, and/or the like. The polymer core 102 may have any geometry, thickness T₁, and/or the like that enables the polymer core 102 and/or the polymeric material 100 to function, for example as described and/or illustrated herein. In some implementations, the polymer core 102 is a tape, a film, a membrane, and/or the like.

Referring now to the metallic layers 104 and 106 of the polymeric material 100, the metallic layer 104 extends on the side 110 of the polymer core 102, and the metallic layer 106 extends on the side 112 of the polymer core 102. Accordingly, the metallic layers 104 and 106 define respective sides 116 and 118 of the polymeric material 100. Each metallic layer 104 and 106 includes one or more electrically conductive metallic materials such that the metallic layers 104 and 106 are each electrically conductive. The electrical conductivity of the metallic layers 104 and 106 provides the polymeric material 100 with electrical conductivity along the sides 116 and 118, respectively, of the polymeric material 100. For example, the electrical conductivity of the metallic layer 104 provides the side 116 of the polymeric material 100 with electrically conductive paths along a width W and along a length L of the polymeric material 100. Moreover, and for example, the electrical conductivity of the metallic layer 106 provides the side 118 of the polymeric material 100 with electrically conductive paths along the width W and length L of the polymeric material 100.

Although the metallic layers 104 and 106 are each illustrated in FIGS. 1 and 2 as a single layer, each of the metallic layers 104 and 106 may include any number of sub-layers. In some implementations, the metallic layer 104 and/or the metallic layer 106 includes only a single sub-layer (i.e., the layer 104 and/or 106 is a single, continuous layer), for example as is shown in FIGS. 1 and 2. Each sub-layer may be comprised of a single metallic material or may be a composite of two or more materials (wherein at least one of the materials is an electrically conductive metallic material). Each metallic layer 104 and 106 may include any number of different materials and any number of different electrically conductive metallic materials. Examples of electrically conductive metallic materials that may be included within the metallic layers 104 and/or 106 include, but are not limited to, silver, copper, annealed copper, gold, steel, stainless steel, aluminum, beryllium, magnesium, zinc, cobalt, nickel, and/or the like. Examples of other materials that may be included within the metallic layers 104 and/or 106 include, but are not limited to, polymers, resins, epoxies, carbon, and/or the like.

In one example illustrated in FIG. 4, a polymeric material 200 includes a polymer core 202, metallic layers 204 and 206 extending on opposite sides 210 and 212, respectively, of the polymer core 202, and metallic links 208 that provide electrically conductive paths (within pores 214 of the polymer core 202) between the metallic layers 204 and 206. Each of the metallic layers 204 and 206 includes a respective sub-layer 204a and 206a of copper extending directly on the respective side 210 and 212, and a respective sub-layer 204b and 206b of silver extending directly on the respective sub-layer 204a and 206a (and thus extending indirectly on the respective side 210 and 212). For example, in some implementations the polymeric material 200 is a silver-plated copper film with a polymer core 202. Each of the metallic layers 204 and 206 may be referred to herein as a “first” metallic layer and/or a “second” metallic layer. Each of the sides 210 and 212 may be referred to herein as a “first” side and/or a “second” side.

Referring again to FIGS. 1 and 2, various parameters of the metallic layers 104 and/or 106 and/or the fabrication thereof may be selected to provide the layers 104 and/or 106, and/or the polymeric material 100, with a predetermined level of electrical conductivity. Examples of parameters of the metallic layers 104 and/or 106 that may be selected to provide the layer 104, the layer 106, and/or the polymeric material 100 with a predetermined level of electrical conductivity include, but are not limited to, a thickness of the metallic layer 104 and/or the metallic layer 106, the type of material(s) included within the metallic layer 104 and/or the metallic layer 106, the number of different types of materials included within the metallic layer 104 and/or the metallic layer 106, the porosity of the metallic layer 104 and/or the metallic layer 106, and/or the like. In some implementations, the level of electrical conductivity and/or level of electrical resistance of the metallic layers 104 and/or 106 is selected to enable the polymeric material 100 to provide a predetermined level of electrical shielding.

As briefly described above, the metallic links 108 provide electrically conductive paths between the metallic layers 104 and 106. As best seen in FIG. 2, each metallic link 108 extends a length within the corresponding pore 114 from an end portion 120 to an opposite end portion 122. The end portion 120 of each metallic link 108 is connected to (e.g., joined to; a continuous, unitary structure with; fused to; linked with; etc.) the metallic layer 104 extending on the side 110 of the polymer core 102. The end portion 122 of each metallic link 108 is connected to (e.g., joined to; a continuous, unitary structure with; fused to; linked with; etc.) the metallic layer 106 extending on the side 112 of the polymer core 102. Accordingly, the metallic links 108 include internal metallic structures that extend within the pores 114 and mechanically connect (e.g., join; form a continuous, unitary structure with; fuse; link; etc.) the metallic layers 104 and 106 together. In some implementations, one or more of the metallic links 108 includes an internal metallic layer that extends within a corresponding pore 114 and mechanically connects (e.g., joins; form a continuous, unitary structure with; fuses; links; etc.) the metallic layers 104 and 106 together. For example, one or more of the metallic links 108 may include a layer that extends on an interior surface 124 of the polymer core 102 that at least partially defines the corresponding pore 114. In some implementations, one or more of the metallic links 108 includes an internal metallic plug, leg, arm, rod, pin, chain, string, pole, column, and/or the like that extends within a corresponding pore 114 and mechanically connects (e.g., joins; form a continuous, unitary structure with; fuses; links; etc.) the metallic layers 104 and 106 together.

Each metallic link 108 includes one or more electrically conductive metallic materials such that the metallic links 108 are each electrically conductive. The electrical conductivity of the metallic links 108 provides the metallic links 108 with electrically conductive paths along the lengths of the metallic links 108. Accordingly, the metallic links 108 provide electrically conductive paths from the metallic layer 104 to the metallic layer 106, and vice versa. In other words, the metallic links 108 provide electrically conductive paths between the metallic layers 104 and 106. The internal metallic structures (e.g., layers, plugs, legs, arms, rods, pins, chains, strings, poles, columns, etc.) of the metallic links 108 conductively bridge the metallic layers 104 and 106 together, for example such that the polymeric material 100 is electrically conductive through the thickness T of the polymeric material 100. In other words, the metallic links 108 are configured such that the polymeric material 100 is electrically conductive through the thickness T thereof.

Although the internal metallic structures of the metallic links 108 are illustrated in FIGS. 1 and 2 as internal metallic layers that each have a single layer, each of the metallic links 108 may include any number of sub-layers. In some implementations, a metallic link 108 includes only a single sub-layer (i.e., the metallic link 108 is a single, continuous layer), for example as is shown in FIGS. 1 and 2. Each sub-layer may be comprised of a single metallic material or may be a composite of two or more materials (wherein at least one of the materials is an electrically conductive metallic material). Each metallic link 108 may include any number of different materials and any number of different electrically conductive metallic materials. Examples of electrically conductive metallic materials that may be included within the metallic links 108 include, but are not limited to, silver, copper, annealed copper, gold, steel, stainless steel, aluminum, beryllium, magnesium, zinc, cobalt, nickel, and/or the like. Examples of other materials that may be included within the metallic links 108 include, but are not limited to, polymers, resins, epoxies, carbon, and/or the like.

In the exemplary implementation illustrated in FIGS. 1 and 2, the pores 114 of the polymer core 102 are partially filled by the metallic links 108 such that the pores 114 include voids 126. In other words, the voids 126 remain within the pores 114 after the metallic links 108 have been installed (e.g., formed, inserted, constructed, etc.) within the pores 114. As best seen in FIG. 2, the voids 126 extend through the thickness T of the polymeric material 100. In other words, the voids 126 extend through the sides 116 and 118, and therebetween, of the polymeric material 100. As such, the voids 126 may provide the polymeric material 100 with porosity. In some implementations, the voids 126 are configured (e.g., size, shape, quantity, density, pattern, etc.) such that the polymeric material 100 is nanoporous and/or microporous, for example having a microstructure wherein the voids 126 are micropores (e.g., have a size equal to or less than approximately 2 nanometers, etc.). The voids 126 illustrated herein (e.g., in FIGS. 1 and 2, etc.) are meant only as exemplary schematic (e.g., simplified, etc.) representations of the voids 126. It should be understood that the geometry of the voids 126 may be more complex than shown herein.

A predetermined porosity of the polymeric material 100 may be selected, for example, via: selection of the configuration (e.g., size, shape, quantity, density, pattern, etc.) of the voids 126; fabrication parameters (e.g., processes, operations, variables, conditions, etc.), for example parameters at which the metallic links 108 are installed, etc.; and/or the like. For example, one or more various parameters of the polymeric material 100 and/or the fabrication thereof may be selected to increase (e.g., maximize, increase to below a level at which the polymeric material 100 loses mechanical structural integrity, etc.) the porosity of the polymeric material 100. For example, the parameters at which the metallic links 108 are installed may affect the configuration (e.g., size, shape, quantity, density, pattern, etc.) of the voids 126.

In some implementations, the polymeric material 100 has a porosity of at least approximately 40%, approximately 50% (i.e., in some implementations the polymeric material 100 is configured to include approximately 50% air), greater than approximately 50%, at least approximately 60%, and/or the like. The polymeric material 100 may include any number of the voids 126, any density of the voids 126, and each voids 126 may have any size and/or shape, that provides the polymer core 102 with the predetermined porosity.

Various parameters of the metallic links 108 and/or the fabrication thereof may be selected to provide the links 108 and/or the polymeric material 100 with a predetermined level of electrical conductivity. Examples of parameters of the metallic links 108 that may be selected to provide the metallic links 108 and/or the polymeric material 100 with a predetermined level of electrical conductivity include, but are not limited to, the size (e.g., a thickness, a width, a diameter, etc.) of a metallic link 108, the shape of a metallic link 108, the type of material(s) included within a metallic link 108, the number of different types of materials included within a metallic link 108, the amount (e.g., percentage, volume, etc.) of a pore 114 that is filled by the corresponding metallic link 108, the porosity of the polymeric material 100, and/or the like.

Various parameters of the voids 126, the metallic links 108, and/or the fabrication thereof may be selected to provide the electrical paths between the metallic layers 104 and 106 provided by the metallic links 108, and/or the polymeric material 100, with a predetermined level of electrical resistivity. Examples of parameters of the voids 126, the metallic links 108, and/or the fabrication thereof that may be selected to provide the electrical paths between the metallic layers 104 and 106 provided by the metallic links 108, and/or the polymeric material 100, with the predetermined level of electrical resistivity include, but are not limited to, the size (e.g., thickness, width, diameter, etc.) of a void 126, the shape of a void 126, the size (e.g., thickness, width, diameter, etc.) of a metallic link 108, the shape of a metallic link 108, the type of material(s) included within a metallic link 108, the number of different types of materials included within a metallic link 108, the porosity of the polymeric material 100, and/or the like. The presence of the voids 126 may provide the electrical paths between the metallic layers 104 and 106 provided by the metallic links 108 with a relatively low level of electrical resistivity, for example an electrical resistance of equal to or below approximately 1 microohm, an electrical resistance of equal to or below approximately 1 milliohm, and/or the like. In some implementations, the level of electrical conductivity and/or level of electrical resistance of one or more of the metallic links 108 is selected to enable the polymeric material 100 to provide a predetermined level of electrical shielding.

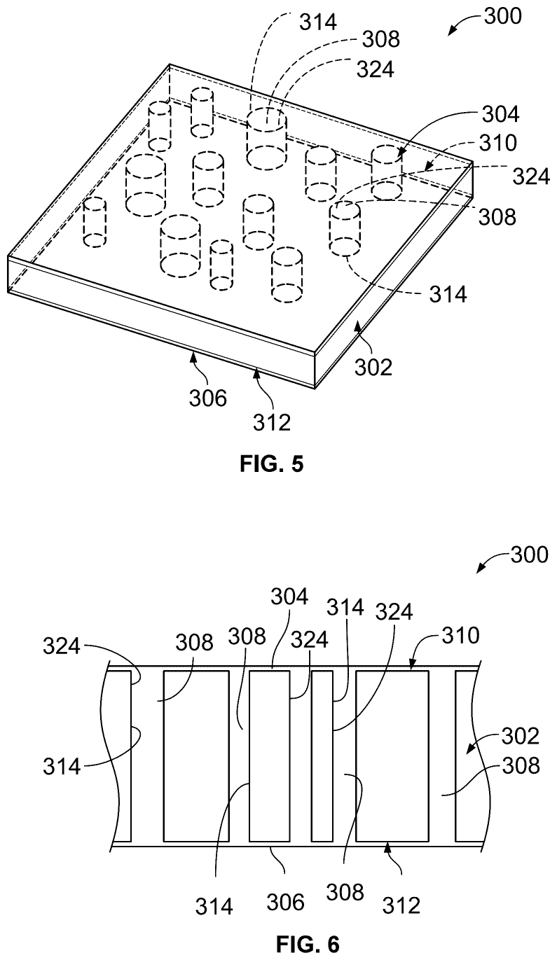

In some implementations, the pores 114 of the polymer core 102 are approximately completely filled by the metallic links 108. In some implementations, one or more of the pores 114 is partially filled by the metallic links 108 such that the pore(s) 114 includes a void 126, while one or more of the pores 114 is approximately completely filled by the metallic links 108. FIGS. 5 and 6 illustrate an example of a polymeric material 300 wherein pores 314 of a polymer core 302 are approximately completely filled by corresponding metallic links 308. The polymeric material 300 includes the polymer core 302, metallic layers 304 and 306 extending on opposite sides 310 and 312, respectively, of the polymer core 302, and the metallic links 308, which provide electrically conductive paths between the metallic layers 304 and 306. Each of the metallic layers 304 and 306 may be referred to herein as a “first” metallic layer and/or a “second” metallic layer. Each of the sides 310 and 312 may be referred to herein as a “first” side and/or a “second” side.

As shown in FIGS. 5 and 6, the pores 314 of the polymer core 302 are each approximately completely filled by the corresponding metallic links 308, for example such that approximately no voids remain within the pores 314. For example, in the illustrated implementation of FIGS. 5 and 6, the metallic links 308 define plugs that approximately completely fill the corresponding pores 314. In some other implementations, one or more of the metallic links 308 defines a plug that substantially fills the corresponding pore 314 of the polymer core 302. Whether approximately completely or substantially filling the corresponding pore 314, the plug of the metallic link 308 may be, for example: fabricated by depositing one or more layers on an interior surface 324 of the polymer core 302 that at least partially defines the corresponding pore 314; a pre-fabricated plug that is inserted into to the corresponding pore 314 (such as, but not limited to: magnetically; electrically, for example using electrical charge; mechanically, for example using a pressure differential, using a vacuum, by impregnating the plug into the corresponding pore 314, by pressing the plug into the corresponding pore 314, etc.; and/or the like) and electrically connected (e.g., fused, welded, soldered, etc.) to the metallic layers 304 and 306; etc.

Various parameters of the metallic links 308 and/or the fabrication thereof may be selected to provide the links 308, and/or the polymeric material 300, with a predetermined level of electrical conductivity. Examples of parameters of the metallic links 308 that may be selected to provide the metallic links 308 and/or the polymeric material 300 with a predetermined level of electrical conductivity include, but are not limited to, the size (e.g., a thickness, a width, a diameter, etc.) of a metallic link 308, the shape of a metallic link 308, the type of material(s) included within a metallic link 108, the number of different types of materials included within a metallic link 308, and/or the like.

Various parameters of the metallic links 308 and/or the fabrication thereof may be selected to provide the electrical paths between the metallic layers 304 and 306 provided by the metallic links 308, and/or the polymeric material 300, with a predetermined level of electrical resistivity. Examples of parameters of the metallic links 308 and/or the fabrication thereof that may be selected to provide the electrical paths between the metallic layers 304 and 306 provided by the metallic links 308 and/or the polymeric material 300 with the predetermined level of electrical resistivity include, but are not limited to, the size (e.g., thickness, width, diameter, etc.) of a metallic link 308, the shape of a metallic link 308, the type of material(s) included within a metallic link 308, the number of different types of materials included within a metallic link 308, and/or the like. The approximately complete filling of the pores 314 by the metallic links 308 may provide the electrical paths between the metallic layers 304 and 306 provided by the metallic links 308 with a relatively higher level (e.g., compared to the metallic links 108 of the polymeric material 100, etc.) of electrical resistivity, for example an electrical resistance of equal to or above approximately one microohm, an electrical resistance of equal to or above approximately one milliohm, and/or the like. In some implementations, the level of electrical conductivity and/or level of electrical resistance of one or more of the metallic links 308 is selected to enable the polymeric material 300 to provide a predetermined level of electrical shielding.

Referring again to FIGS. 1 and 2, the electrically conductive polymeric material 100 includes the porous polymer core 102 that has been metallized with the metallic links 108 and the metallic layers 104 and 106 such that the polymeric material 100 is electrically conductive through the thickness T thereof. The porosity of the polymer core 102 enables the metallization thereof to conductively bridge the opposite sides 116 and 118 (e.g., the metallic layers 104 and 106, etc.) together resulting in the polymeric material 100 being conducive through the thickness T thereof. In the absence of the conductive bridging provided by the metallic links 108, the polymeric material 100 would include two electrically conductive layers (e.g., the metallic layers 104 and 106, etc.) separated by an electrical insulator, and thus possibly function as a capacitor. Accordingly, the metallic links 108 may increase the electrical conductivity, increase the electrical shielding capability, decrease the capacitance, and/or the like of the polymeric material 100, for example as compared to polymer materials that include two electrically conductive layers separated by an electrical insulator. The polymeric material 100 thus operates in an unconventional manner, for example to provide improved electrical performance of polymer materials (e.g., improved electrical conductivity, improved electrical shielding capability, reduced unwanted capacitive behavior, etc.).

Although the illustrated segment of the polymeric material 100 is approximately square, the polymeric material 100 may have any geometry, thickness T, and/or the like that enables the polymeric material 100 to function, for example as described and/or illustrated herein. In some implementations, the polymeric material 100 is elongate, for example along the length L, along the width W, etc. In some implementations, the polymeric material 100 is a tape, a film, a membrane, and/or the like.

Any suitable method, process, operation, treatment, and/or the like may be used to fabricate (e.g., metallize the polymer core 102, etc.) the polymeric material 100, such as, but not limited to, forming (e.g., deposition, coating, painting, adhering, galvanizing, wrapping, additively manufacturing, constructing, etc.), inserting, and/or the like. Examples of deposition processes that may be used to fabricate the polymeric material 100 include, but are not limited to, plating, wet plating, vapor deposition, chemical deposition, ion deposition, sputtering (e.g., physical sputtering, cold sputtering, electronic sputtering, potential sputtering, chemical sputtering, etc.), electrodeposition (e.g., electroplating, electrochemical deposition, pulse electroplating, brush electroplating, electroless deposition, etc.), electroforming, and/or the like. Examples of additive manufacturing processes that may be used to fabricate the polymeric material 100 include, but are not limited to, solid state additive manufacturing, stereolithography, selective laser sintering (SLS), a fused filament fabrication (FFF), selective laser melting (SLM) processes, and/or the like. Examples of insertion processes that may be used to fabricate the polymeric material 100 include, but are not limited to, magnetic, electrical (e.g., using electrical charge, etc.), mechanical (e.g., using a pressure differential, using a vacuum, impregnating, pressing, etc.), and/or the like. For example, the metallic links 108 may be inserted into the pores 114 and thereafter electrically connected (e.g., fused, welded, soldered, etc.) to the metallic layers 104 and 106. In some implementations (e.g., for a relatively hydrophobic polymer, etc.), one or more surface treatments (e.g., plasma discharge, corona discharge, etc.) may be applied to the polymer core 102, for example to improve bonding of the metallic links 108 and/or the metallic layers 104 and/or 106 to the corresponding surfaces of the polymer core 102 (e.g., to activate a surface for adsorption of metallic atoms, etc.).

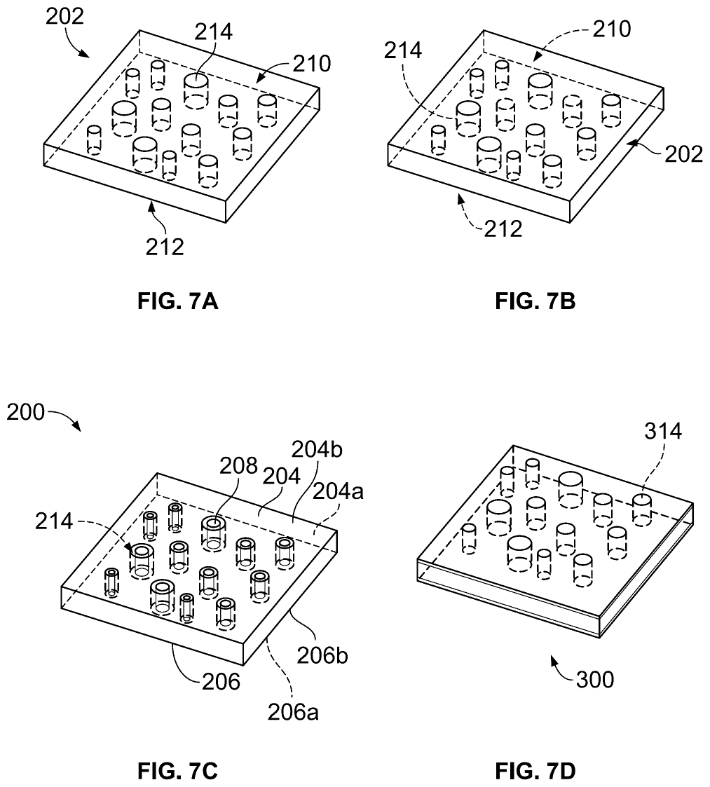

FIG. 7 illustrates one example of including forming processes to fabricate the polymeric materials disclosed herein according to an implementation. For example, FIG. 7 illustrates one example of including forming processes to fabricate the polymeric material 200 shown in FIG. 4. FIG. 7a illustrates the polymer core 202 of the polymeric material 200 before the polymer core 202 has been metallized. FIG. 7b illustrates the polymer core 202 after a vapor deposition process has been performed to deposit copper onto the sides 210 and 212 of the polymer core 202 and within the pores 214 of the polymer core 202. Optionally, one or more plating processes is performed to deposit additional copper thickness on the side 210, the side 212, and/or within the pores 214. The resulting polymeric material 200 including the metallic layers 204 and 206 and the metallic links 208 is illustrated in FIG. 7c. Optionally, silver is deposited on the copper sub-layers 204a and 206a to create the silver sub-layers 204b and 206b of the metallic layers 204 and 206, for example to prevent oxidation of the copper.

In the exemplary implementation shown in FIG. 7c, the pores 214 of the polymer core 202 are partially filled by the metallic links 208 such that the pores 214 include voids 226. Optionally, (e.g., before forming the optional silver sub-layers 204b and 206b, etc.), one or more plating processes is performed to deposit additional copper to approximately completely fill the pores 214 of the polymer core 202 with the metallic links 208, for example such that approximately no voids remain within the pores 214. The resulting polymeric material 300 with the pores 314 approximately completely filled in is illustrated in FIG. 7d. Accordingly, FIGS. 7a-7d also illustrate one example of including forming processes to fabricate the polymeric material 300 shown in FIGS. 6 and 7.

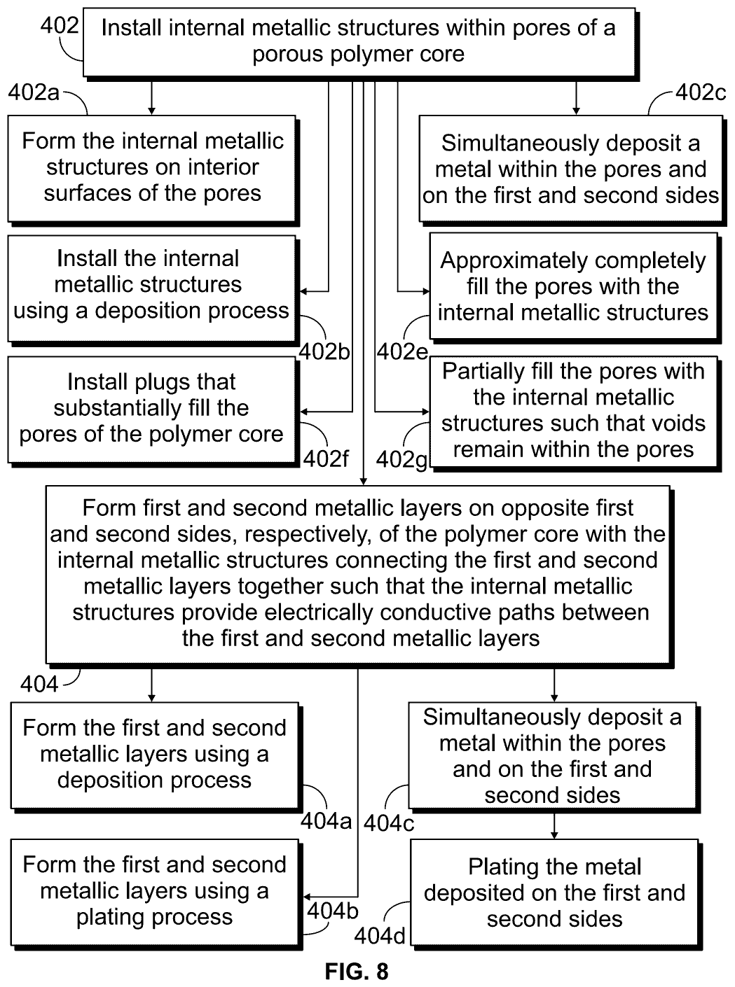

FIG. 8 illustrates a method 400 for fabricating a polymeric material (e.g., the polymeric material 100 shown in FIGS. 1 and 2, the polymeric material 200 shown in FIGS. 4 and 7c, the polymeric material 300 shown in FIGS. 5, 6, and 7d, etc.). The method 400 includes installing, at 402, internal metallic structures within pores of a porous polymer core. At 404, the method 400 includes forming first and second metallic layers on opposite first and second sides, respectively, of the polymer core with the internal metallic structures connecting the first and second metallic layers together such that the internal metallic structures provide electrically conductive paths between the first and second metallic layers.

Optionally, installing at 402 the internal metallic structures within the pores of the polymer core includes forming, at 402a, the internal metallic structures on interior surfaces of the pores. In some implementations, at least one of installing at 402 the internal metallic structures or forming at 404 the first and second metallic layers includes using, at 402b or 404a, respectively, a deposition process. In some implementations, forming at 404 the first and second metallic layers includes using, at 404b, a plating process.

Optionally, installing at 402 the internal metallic structures and forming at 404 the first and second metallic layers includes simultaneously depositing, at 402c, a metal within the pores and on the first and second sides. In some implementations, installing at 402 the internal metallic structures and forming at 404 the first and second metallic layers includes simultaneously depositing, at 404c a metal within the pores and on the first and second sides of the polymer core; and forming at 404 the first and second metallic layers further includes plating, at 404d, the metal deposited on the first and second sides.

In some implementations, installing at 402 the internal metallic structures includes approximately completely filling, at 402e, the pores with the internal metallic structures. In some implementations, installing at 402 the internal metallic structures includes installing, at 402f, plugs that substantially fill the pores of the polymer core. Optionally, installing at 402 the internal metallic structures includes partially filling, at 402j, the pores with the internal metallic structures such that voids remain within the pores.

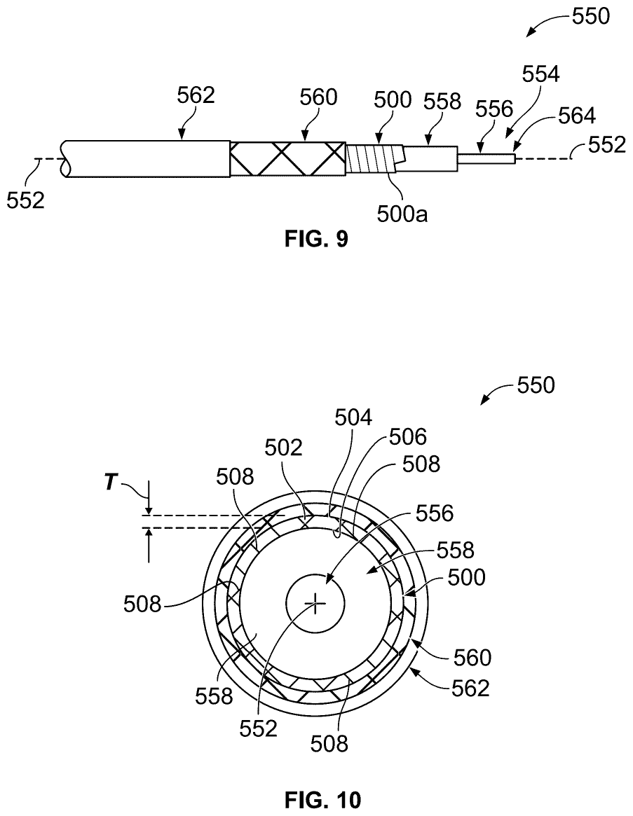

Referring now to FIGS. 9 and 10, elevational and cross-sectional views of an electrical cable 550 are provided to illustrate one exemplary application of the polymeric materials disclosed herein (e.g., the polymeric material 100 shown in FIGS. 1 and 2, the polymeric material 200 shown in FIGS. 4 and 7c, the polymeric material 300 shown in FIGS. 5, 6, and 7d, etc.). The electrical cable 550 extends a length along a longitudinal axis 552 from an end portion 554 (not shown in FIG. 10) to an opposite end portion (not shown). In the exemplary implementation shown in FIGS. 9 and 10, the electrical cable 550 includes an inner conductor 556, a dielectric layer 558, a polymeric material 500, an optional shield 560, and a jacket 562. A combination of the inner conductor 556 and the dielectric layer 558 may be referred to herein as a “cable core”. As best seen in FIG. 9, the inner conductor 556 extends a length along the longitudinal axis 552 from an end portion 564 (not shown in FIG. 10) to an opposite end portion (not shown). The dielectric layer 558 extends around the inner conductor 556 and the polymeric material 500 extends around the dielectric layer 558. The shield 560 extends around the polymeric material 500 and the jacket 562 extends around the shield 560. Beginning at the end portion 554 of the electrical cable 550, portions of the dielectric layer 558, the polymeric material 500, the shield 560, and the jacket 562 have been progressively removed from FIG. 9 to illustrate the construction of the electrical cable 550 more clearly.

The dielectric layer 558 extends radially (relative to the longitudinal axis 552) between the inner conductor 556 and the polymeric material 500 such that the dielectric layer 558 electrically insulates the inner conductor 556 from the polymeric material 500. The dielectric layer 558 may be applied around the inner conductor 556 in any arrangement, configuration, manner, with any geometry, and/or the like that enables the dielectric layer 558 to function, for example as described and/or illustrated herein. For example, the dielectric layer 558 may be: axially-wrapped around the inner conductor 556; helically-wrapped around the inner conductor 556; fabricated as a tube, sheath, and/or the like (e.g., via extrusion, etc.); and/or the like.

The polymeric material 500 includes a polymer core 502, metallic layers 504 and 506, and metallic links 508. The polymer core 502, metallic layers 504 and 504, and metallic links 508 are not shown in FIG. 9 for clarity. The metallic links 508 provide electrically conductive paths between the metallic layers 504 and 506, for example such that the polymeric material 500 is electrically conductive through a thickness T of the polymeric material 500. As shown in FIGS. 9 and 10, the polymeric material 500 extends around the inner conductor 556. As described above with respect to the polymeric materials disclosed herein (e.g., the polymeric material 100 shown in FIGS. 1 and 2, the polymeric material 200 shown in FIGS. 4 and 7c, the polymeric material 300 shown in FIGS. 5, 6, and 7d, etc.), the polymeric material 500 is electrically conductive. Accordingly, the polymeric material 500 is configured to electrically shield the inner conductor 556, for example to facilitate minimizing leakage of radio-frequency interference (RFI) and/or reducing or preventing electromagnetic interference (EMI) disturbances from distorting signals carried by the cable 550. In some implementations, the polymeric material 500 performs one or more functions of an outer conductor of the cable 550. In other words, in some implementations the polymeric material 500 defines an outer conductor of the electrical cable 550 (i.e., an outer conductor of the electrical cable 550 includes the polymeric material 500). Each of the metallic layers 504 and 506 may be referred to herein as a “first” metallic layer and/or a “second” metallic layer.

The optional shield 560 is configured to provide mechanical axial strength to the electrical cable 550 and/or to restrain the layers of the cable 550 that the shield 560 extends around (e.g., the inner conductor 556, the dielectric layer 558, the polymeric material 500, etc.). In some implementations, the shield 560 includes a plurality of wires and/or strands that are braided and/or served together. Optionally, the shield 560 is electrically conductive, for example to provide electrical shielding of the inner conductor 556. Exemplary materials for the shield 560 include, but are not limited to, silver-plated copper, silver-plated copper-clad steel, stainless steel, carbon fiber, and/or the like. In some implementations, the shield 560 performs one or more functions of an outer conductor of the electrical cable 550 (e.g., in addition or alternative to the polymeric material 500, etc.).

The jacket 562 is optionally fabricated from an electrically insulating material. In addition or alternatively, the jacket 562 may be fabricated from an electrically conductive material, for example to provide electrical shielding. The jacket 562 is optionally fabricated from a material that facilitates protecting the internal structure of the electrical cable 550 from environmental threats such as, but not limited to, dirt, debris, heat, cold, fluids, impact damage, and/or the like. Suitable electrically insulating materials for the jacket 562 include, but are not limited to, a polyimide, polyester, a thermoplastic, a thermoset plastic, and/or the like.

In some implementations, the electrical cable 550 includes two or more layers of the polymeric material 500. The electrical cable 550 may include any number of layers of the polymeric material 500. In the exemplary implementation of FIGS. 9 and 10, the electrical cable 550 includes one (i.e., a single) layer 500a of the polymeric material 500. Moreover, in the exemplary implementation of FIGS. 9 and 10, the polymeric material layer 500a extends radially (relative to the longitudinal axis 552) between the dielectric layer 558 and the shield 560, but the polymeric material 500 is not limited to extending radially between the dielectric layer 558 and the shield 560. Rather, each layer of the polymeric material 500 included within an electrical cable may have any radial position within the electrical cable 550 that enables the polymeric material 500 to function, for example as described and/or illustrated herein (e.g., to electrically shield the inner conductor 556, etc.). For example, in some implementations, in addition or alternative to the polymeric material layer 500a, the electrical cable 550 includes one or more layers of the polymeric material 500 that extend around the shield 560 (e.g., radially between the shield 560 and the jacket 562, etc.).

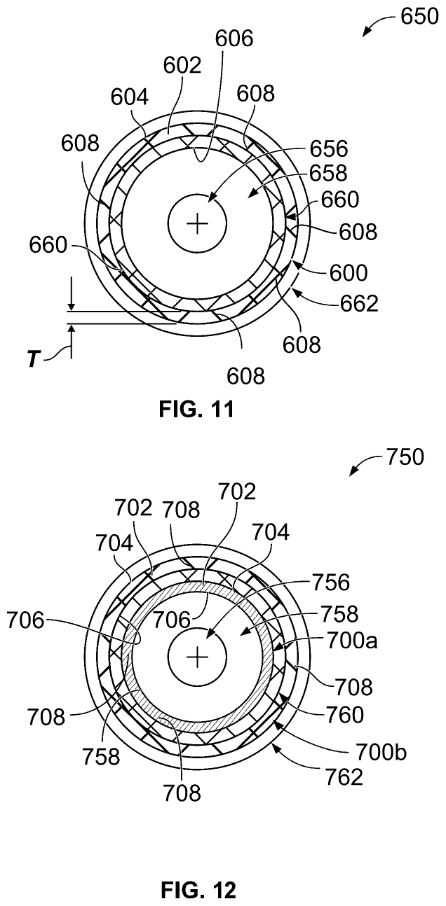

For example, FIG. 11 illustrates an implementation of an electrical cable 650 that includes an inner conductor 656, a dielectric layer 658, an optional shield 660, a polymeric material 600, and a jacket 662. A combination of the inner conductor 656 and the dielectric layer 658 may be referred to herein as a “cable core”. The dielectric layer 658 extends around the inner conductor 656, the shield 660 extends around the dielectric layer 658, the polymeric material 600 extends around the shield 660, and the jacket 662 extends around the polymeric material 600.

The polymeric material 600 includes a polymer core 602, metallic layers 604 and 606, and metallic links 608. The metallic links 608 provide electrically conductive paths between the metallic layers 604 and 606, for example such that the polymeric material 600 is electrically conductive through a thickness T of the polymeric material 600. As shown in FIG. 11, the polymeric material 600 extends around the inner conductor 656. The polymeric material 600 is electrically conductive. Accordingly, the polymeric material 600 is configured to electrically shield the inner conductor 656, for example to facilitate minimizing leakage of radio-frequency interference (RFI) and/or reducing or preventing electromagnetic interference (EMI) disturbances from distorting signals carried by the cable 650. In some implementations, the polymeric material 600 performs one or more functions of an outer conductor of the cable 650. In other words, in some implementations the polymeric material 600 defines an outer conductor of the electrical cable 650 (i.e., an outer conductor of the electrical cable 650 includes the polymeric material 600). The polymeric material 600 may be applied around the inner conductor 656 and the dielectric layer 658 utilizing conventional (e.g., standard, etc.) dielectric tape wrapping equipment, thereby reducing the complexity and challenges of the wrapping process (e.g., a helical wrapping process, an axial wrapping process, etc.). Each of the metallic layers 604 and 606 may be referred to herein as a “first” metallic layer and/or a “second” metallic layer.

Another example includes the implementation of an electrical cable 750 shown in FIG. 12. The electrical cable 750 includes an inner conductor 756, a dielectric layer 758, a polymeric material layer 700a, an optional shield 760, a polymeric material layer 700b, and a jacket 762. A combination of the inner conductor 756 and the dielectric layer 758 may be referred to herein as a “cable core”. The dielectric layer 758 extends around the inner conductor 756, the polymeric material layer 700a extends around the dielectric layer 758, the shield 760 extends around the polymeric material layer 700a, the polymeric material layer 700b extends around the shield 760, and the jacket 762 extends around the polymeric material layer 700b.

The polymeric material layers 700a and 700b include polymer cores 702, metallic layers 704 and 706, and metallic links 708. The metallic links 708 provide electrically conductive paths between the metallic layers 704 and 706, for example such that the polymeric material layers 700a and 700b are electrically conductive through a thickness T thereof. The polymeric material layers 700a and 700b extend around the inner conductor 756. The polymeric material layers 700a and 700b are electrically conductive. Accordingly, the polymeric material layers 700a and 700b are configured to electrically shield the inner conductor 756, for example to facilitate minimizing leakage of radio-frequency interference (RFI) and/or reducing or preventing electromagnetic interference (EMI) disturbances from distorting signals carried by the cable 750. In some implementations, the polymeric material layer 700a and/or the polymeric material layer 700b performs one or more functions of an outer conductor of the cable 750. In other words, in some implementations the polymeric material layer 700a and/or the polymeric material layer 700b defines an outer conductor of the electrical cable 750 (i.e., an outer conductor of the electrical cable 750 includes the polymeric material layer 700a and/or 700b). Each polymeric material layer 700a and 700b may be applied around the inner conductor 756 and the dielectric layer 758 utilizing conventional (e.g., standard, etc.) dielectric tape wrapping equipment, thereby reducing the complexity and challenges of the wrapping process (e.g., a helical wrapping process, an axial wrapping process, etc.). Each of the metallic layers 704 and 706 may be referred to herein as a “first” metallic layer and/or a “second” metallic layer.

Referring again to FIGS. 9 and 10, each layer of the polymeric material 500 may be applied around the inner conductor 556 (and/or any intervening layers of the electrical cable 550) in any arrangement, configuration, manner, with any geometry, and/or the like that enables the polymeric material 500 to function, for example as described and/or illustrated herein (e.g., to electrically shield the inner conductor 556, etc.). For example, each layer of the polymeric material 500 may be: axially-wrapped around the inner conductor 556; helically-wrapped around the inner conductor 556 (e.g., the helical wrapping of the polymeric material 500 shown in FIG. 9, the helical wrapping of the polymeric material 600 shown in FIG. 11, the helical wrapping of the polymeric material layers 700a and 700b shown in FIG. 12, etc.); fabricated as a tube, sheath, and/or the like (e.g., via extrusion, etc.); and/or the like. In some implementations, the polymeric material 500 includes two or more layers that are applied around the inner conductor 556 differently as compared to one or more of each other.

When wrapped around the inner conductor 556, the winding turns of a layer of the polymeric material 500 may have any lay angle, any winding direction, any amount of overlap of adjacent winding turns, any amount of spacing between adjacent winding turns, and/or the like that enables the polymeric material 500 to function, for example as described and/or illustrated herein (e.g., to electrically shield the inner conductor 556, etc.). In some implementations, the polymeric material 500 includes two or more layers that are wrapped with different lay angles, different winding directions, different overlaps, different spacings, and/or the like as compared to one or more of each other. For example, the polymeric material layers 700a and 700b are shown in FIG. 12 as being helically-wrapped with different winding directions as compared to each other. The polymeric material 500 may be applied around the inner conductor 556 and the dielectric layer 558 utilizing conventional (e.g., standard, etc.) dielectric tape wrapping equipment, thereby reducing the complexity and challenges of the wrapping process (e.g., a helical wrapping process, an axial wrapping process, etc.).

Although the exemplary implementation of the electrical cable 550 is shown as including one inner conductor 556 that extends concentrically (about the longitudinal axis 552) relative to the polymeric material 500 (such that the exemplary electrical cable 550 is a coaxial cable), the electrical cable 550 may include any number of the inner conductor 556, for example two or more of the inner conductor 556. For example, the electrical cable 550 may have any construction that includes any number of inner conductors 556 surrounded by any number of the outer conductors with any number of dielectric layers extending radially therebetween. Examples of various constructions of the electrical cable 550 include, but are not limited to, coaxial cables (e.g., the exemplary cable 550 shown herein, etc.), twin-axial cables, shielded parallel pairs, cables that include one or more twisted pairs of the inner conductor 556, cables that include two or more cores that each include one or more of the inner conductor 556 surrounded by at least one dielectric layer, and/or the like.

In implementations of the electrical cable 550 that include more than one of the inner conductor 556: at least one discrete dielectric layer 558 may be applied (e.g., wrapped around, fed over, formed over, etc.) around each inner conductor 556 or each pair of the inner conductor 556; and/or at least one dielectric layer 558 may extend around all of the inner conductors 556.

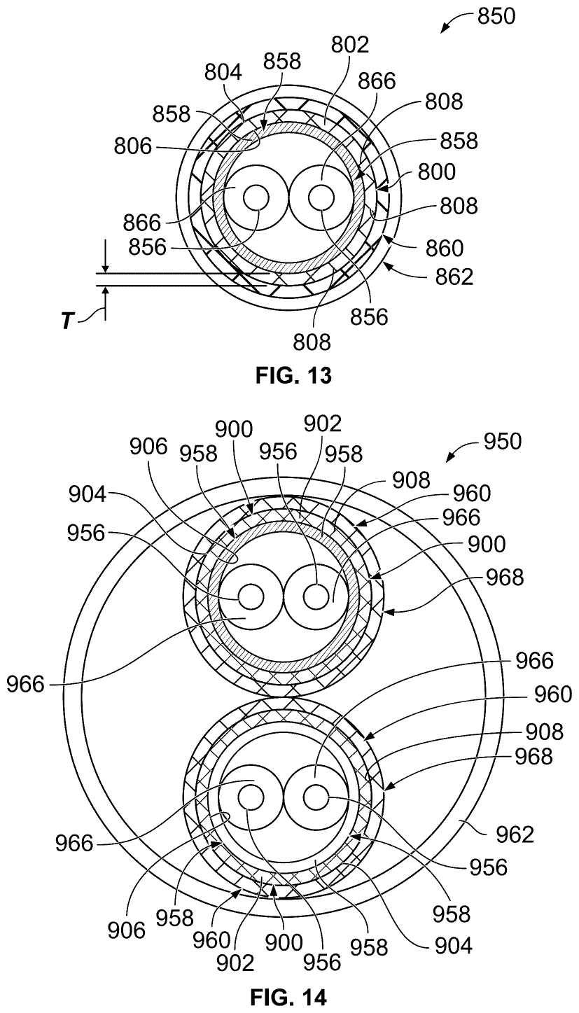

For example, FIG. 13 illustrates an implementation of an electrical cable 850 that includes a pair of inner conductors 856, an optional dielectric layer 858, a polymeric material 800, an optional shield 860, and a jacket 862. A combination of the inner conductors 856 and the dielectric layer 858 may be referred to herein as a “cable core”. Optionally, the pair of inner conductors 856 is a twisted pair. In the exemplary implementation of FIG. 13, each of the inner conductors 856 is surrounded by a discrete insulating layer 866, and the optional dielectric layer 858 extends around the pair of inner conductors 856. In some other implementations, the pair of inner conductors 856 do not include the discrete insulating layers 866.

The polymeric material 800 includes a polymer core 802, metallic layers 804 and 806, and metallic links 808. The metallic links 808 provide electrically conductive paths between the metallic layers 804 and 806, for example such that the polymeric material 800 is electrically conductive through a thickness T of the polymeric material 800. The polymeric material 800 is configured to electrically shield the inner conductors 856, for example to facilitate minimizing leakage of radio-frequency interference (RFI) and/or reducing or preventing electromagnetic interference (EMI) disturbances from distorting signals carried by the cable 850. In some implementations, the polymeric material 800 performs one or more functions of an outer conductor of the cable 850. The polymeric material 800 may be applied around the inner conductors 856 utilizing conventional (e.g., standard, etc.) dielectric tape wrapping equipment, thereby reducing the complexity and challenges of the wrapping process (e.g., a helical wrapping process, an axial wrapping process, etc.). Each of the metallic layers 804 and 806 may be referred to herein as a “first” metallic layer and/or a “second” metallic layer.

In another example, FIG. 14 illustrates an implementation wherein an electrical cable 950 includes two cable cores 968 surrounded by a jacket 962. Each cable core 968 includes a pair of inner conductors 956, an optional dielectric layer 958, a polymeric material 900, and an optional shield 960. Optionally, one or more of the pairs of inner conductors 956 is a twisted pair. Within each cable core 968, each of the inner conductors 956 is surrounded by a discrete insulating layer 966, and the optional dielectric layer 958 extends around the pair of inner conductors 956. In some other implementations, within one or more of the cable cores 968, the pair of inner conductors 956 do not include the discrete insulating layers 966.

The polymeric material 900 includes a polymer core 902, metallic layers 904 and 906, and metallic links 908. The metallic links 908 provide electrically conductive paths between the metallic layers 904 and 906, for example such that the polymeric material 900 is electrically conductive through a thickness T of the polymeric material 900. The polymeric material 900 is configured to electrically shield the inner conductors 956, for example to facilitate minimizing leakage of radio-frequency interference (RFI) and/or reducing or preventing electromagnetic interference (EMI) disturbances from distorting signals carried by the cable 950. In some implementations, the polymeric material 900 performs one or more functions of an outer conductor of the corresponding cable core 968. The polymeric material 900 may be applied around the inner conductors 956 utilizing conventional (e.g., standard, etc.) dielectric tape wrapping equipment, thereby reducing the complexity and challenges of the wrapping process (e.g., a helical wrapping process, an axial wrapping process, etc.). Each of the metallic layers 904 and 906 may be referred to herein as a “first” metallic layer and/or a “second” metallic layer.

Referring again to FIGS. 9 and 10, various parameters of the polymeric material 500 and/or the fabrication thereof may be selected to enable the polymeric material 500 to provide the electrical cable 550 with a predetermined level of electrical shielding, for example to facilitate minimizing leakage of radio-frequency interference (RFI) and/or reducing or preventing electromagnetic interference (EMI) disturbances from distorting signals carried by the cable 550. Examples of the various parameters of the polymeric material 500 and/or the fabrication thereof that may be selected include, but are not limited to: the number of layers of the polymeric material 500: the arrangement, configuration, manner, geometry, and/or the like of how each layer of the polymeric material 500 is applied over the inner conductor 556 (e.g.; axially-wrapped; helically-wrapped; fabricated as a tube, sheath, and/or the like; lay angle; winding direction; overlap of adjacent winding turns; spacing between adjacent winding turns; etc.); the radial position of the layer(s) of the polymeric material 500 within the cable 550; the level of electrical conductivity of the polymeric material 500 (e.g., through the thickness T thereof, along the length thereof, along the width thereof, etc.); the level of resistivity of the polymeric material 500 (e.g., through the thickness T thereof, along the length thereof, along the width thereof, etc.); a thickness of the metallic layer 504 and/or the metallic layer 506; the type of material(s) included within the metallic layer 104 and/or the metallic layer 106; the number of different types of materials included within the metallic layer 104 and/or the metallic layer 106; the size (e.g., a thickness, a width, a diameter, etc.) of the metallic links 508; the shape of the metallic links 508; the type of material(s) included within the metallic links 508; the number of different types of materials included within the metallic links 508; the amount (e.g., percentage, volume, etc.) of the corresponding pore (not shown) that is filled by the corresponding metallic link 508; the size (e.g., thickness, width, diameter, etc.) of a void (not shown; e.g., the voids 126 shown in FIGS. 1 and 2, etc.), the shape of a void; the porosity of the polymeric material 500; the size (e.g., thickness, width, etc.) of the polymeric material 500; and/or the like.

In some implementations, the polymer core 502 of the polymeric material 500 is cross-linked. Cross-linking decreases the temperature sensitivity (i.e., increases the heat resistance) of the polymer core 502 of the polymeric material 100 (e.g., increases the glass transition temperature of the polymer core 502, etc.). Cross-linking of the polymer core 502 thus enables the polymeric material 500 and thereby the electrical cable 550 to withstand higher temperatures. Accordingly, the cross-linked polymer core 502 is suitable for use in cabling applications wherein the cable 550 (during use, termination, or construction thereof) is subjected to higher temperatures. For example, cross-linking the polymer core 502 of the polymeric material 500 may enable the electrical cable 550 to be subjected to a soldering, welding, laser welding, sintering, and/or other heating process (e.g.; for terminating the inner conductor 556, he polymeric material 500, the shield 560, and/or other components of the electrical cable 550 to various components, such as connectors, printed circuit boards, etc.; for extrusion of one or more other components of the cable 550, such as, but not limited to, the jacket 562, etc.; for shrinking one or more other components of the cable 550, for example the jacket 52, a strain relief boot, etc.; etc.) without compromising the mechanical structural integrity and/or electrical signal transmission characteristics of the electrical cable 550. Moreover, and for example, cross-linking the polymer core 502 of the polymeric material 500 may enable the electrical cable 550 to be used at higher environmental temperatures without compromising the mechanical structural integrity and/or electrical signal transmission characteristics of the electrical cable 550. The polymer cores disclosed herein may be cross-linked using any suitable method, process, structure, machine, means, and/or the like, such as, but not limited to, electron beam technology, chemical cross-linking, and/or the like.

The polymeric material 500 operates in an unconventional manner, for example to provide improved electrical shielding materials. For example, the polymeric material 500 is less challenging to apply (e.g., wrap, etc.) over the inner conductor 556 and the dielectric layer 558 as compared to flat wire or metal foil, especially as the diameter of the cable core is reduced. For example, the polymeric material 500 may be applied around the inner conductor 556 and dielectric layer 558 utilizing conventional (e.g., standard, etc.) dielectric tape wrapping equipment, thereby reducing the complexity and challenges of the wrapping process (e.g., a helical wrapping process, an axial wrapping process, etc.). The polymeric material 500 reduces or eliminates the challenges, inconsistencies, and variations of applying the flat wire or metal foil over a cable core, thereby resulting in improved electrical shielding (e.g., more effective shielding at relatively high frequencies, etc.). For example, the application of the polymeric material 500 over the inner conductor 556 and the dielectric layer 558 reduces or eliminates inconsistencies in attenuation behavior and transmission losses (e.g., particularly for coaxial and twin-axial cables) and/or reflective losses and instability in the phase and/or time delay as the cable is moved and/or flexed (e.g., as compared to cables including a wrapped flat wire or metal foil, etc.). Accordingly, incorporation of the polymeric material 500 within the electrical cable 550 as an electrical shielding component results in improved signal propagation characteristics of the cable 550, especially at relatively high frequencies, while maintaining a relatively high flexibility and less distortion of the signal with bending (e.g., as compared to at least some known electrical cables, etc.). In certain implementations, the polymeric material 500 used in combination with the shield 560 provides tensile strength to the resulting cable construction.

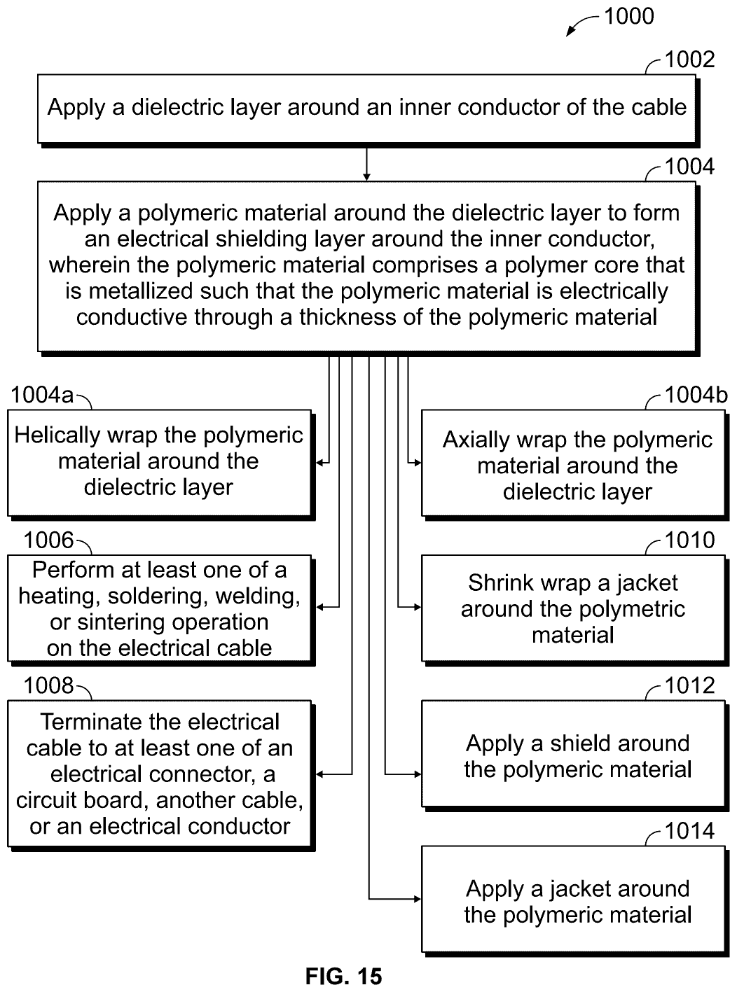

FIG. 15 illustrates a method 1000 for assembling an electrical cable (e.g., the electrical cable 550 shown in FIGS. 9 and 10, the electrical cable 650 shown in FIG. 11, the electrical cable 750 shown in FIG. 12, the electrical cable 850 shown in FIG. 13, the electrical cable 950 shown in FIG. 14, etc.). The method 1000 includes applying, at 1002, a dielectric layer around an inner conductor of the cable. At 1004, the method 1000 includes applying a polymeric material (e.g., the polymeric material 100, 200, 300, 500, 600, 700, 800, and/or 900, etc.) around the dielectric layer to form an electrical shielding layer around the inner conductor, wherein the polymeric material comprises a polymer core that is metallized such that the polymeric material is electrically conductive through a thickness of the polymeric material.

In some implementations, applying at 1004 the polymeric material around the dielectric layer includes helically-wrapping, at 1004a, the polymeric material around the dielectric layer. In some implementations, applying at 1004 the polymeric material around the dielectric layer includes axially-wrapping, at 1004b, the polymeric material around the dielectric layer.

In some implementations, the method 1000 further includes performing, at 1006, at least one of a heating, soldering, welding, or sintering operation on the electrical cable. Optionally, the method 1000 further includes terminating, at 1008, the electrical cable to at least one of an electrical connector, a circuit board, another cable, or an electrical conductor. In some implementations, the method 1000 further includes shrinking-wrapping, at 1010, a jacket around the polymeric material.

Optionally, the method 1000 further includes applying, at 1012, a shield around the polymeric material. In some implementations, the method 1000 further includes applying, at 1014, a jacket around the polymeric material.

The polymeric materials disclosed herein (e.g., the polymeric material 100 shown in FIGS. 1 and 2, the polymeric material 200 shown in FIGS. 4 and 7c, the polymeric material 300 shown in FIGS. 5, 6, and 7d, etc.) are not limited to being used within electrical cables. Rather, the electrical cables disclosed herein (e.g., the cables 550, 50, 750, 850, 950, etc.) are merely one example of an application of the polymeric materials disclosed herein. Examples of other applications of the polymeric materials disclosed herein include, but are not limited to:
biological systems and/or processes (e.g., tissue regeneration, bone regeneration, hemodialysis, artificial kidneys, biological catalysts, chemical biological processes and/or reactions, etc.);
micro support structures and/or nano support structures (e.g., microporous skeletons, nanoporous skeletons, used for fabricating electrodes, etc.);
liquid and/or gas separation, (e.g., separation of biomaterials, oil-water separation, etc.);
hydrogen recovery systems;
fuel cells;
pollution control;
drug release systems;
and/or the like.
   In some implementations, the polymeric materials disclosed herein provide an increased surface area (e.g., as compared to at least some known materials, etc.) for attachment of one or more chemical and/or biological groups to perform one or more chemical and/or biological reactions.

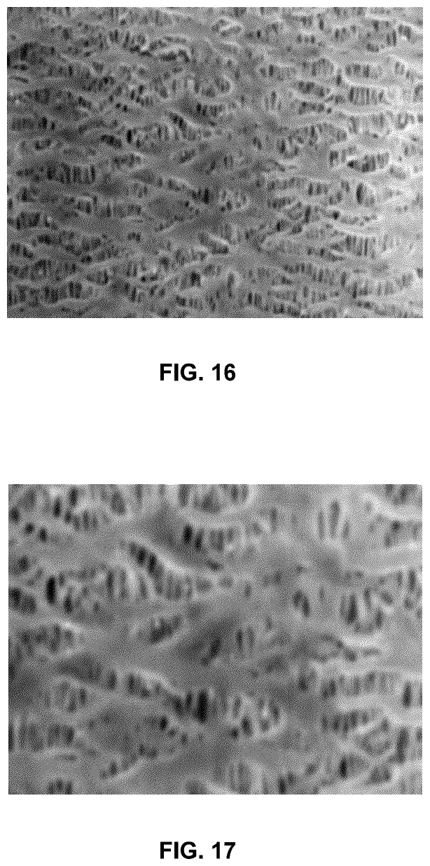

An experimental example of the polymeric materials disclosed herein will now be described. FIGS. 16 and 17 illustrate an exemplary microstructure of a polymer core of a polymeric material according to an example. In other words, FIGS. 16 and 17 illustrate the polymer core of the polymeric material before the polymer core has been metallized according to the disclosure herein. A minimal amount of metal (e.g., gold and/or palladium) may have been formed on the polymer core to enable the images of FIGS. 16 and 17 to be collected (i.e., to enable visualization of the microstructure of the polymer core). FIGS. 16 and 17 have field of views of approximately 13.8 μm and 6.92 μm, respectively.

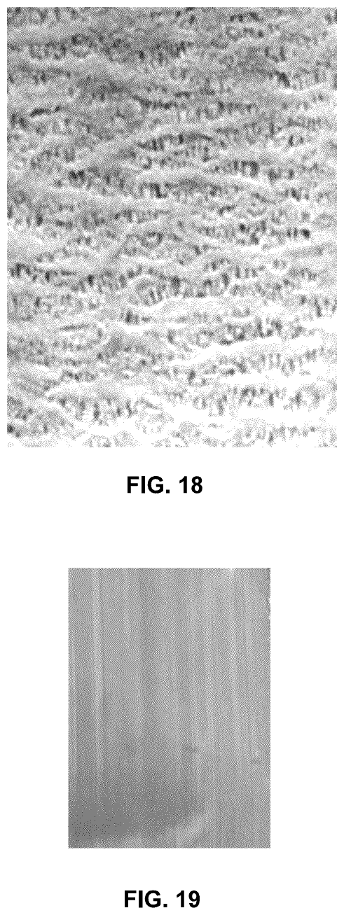

FIG. 18 illustrates the microstructure of the polymeric material after a vapor deposition process has been performed to deposit approximately 300 Angstroms of copper onto the sides of the polymer core and within the pores of the polymer core. FIG. 19 is a plan view of one of the sides of the polymeric material illustrating a surface of the copper layer deposited on the polymer core according to the example. As is apparent from a comparison of FIGS. 16 and 18, the copper layer deposited on the polymer core has reduced the pore size of the polymeric material as compared to the pore size of the polymer core before the copper layer was formed thereon. While both sides of the polymeric material shown in FIG. 18 are electrically conductive (e.g., have an electrical resistance of less than approximately 10,000 ohms), the metallic links formed within the pores by the approximately 300 Angstrom copper layer of the polymeric material shown in FIG. 18 did not provide sufficient electrical conductivity (e.g., have an electrical resistance of equal to or greater than approximately 10,000 ohms) between the opposite sides of the polymeric material (i.e., through the thickness of the polymeric material). FIG. 18 has a field of view of approximately 13.8 μm.

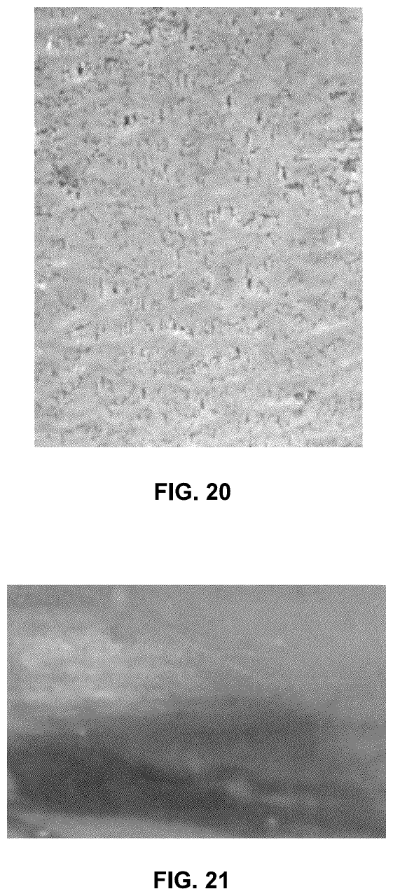

FIG. 20 illustrates the microstructure of the polymeric material after an electroplating process has been performed to form silver over the approximately 300 Angstrom copper layer of the polymeric material. FIG. 21 is a plan view of one of the sides of the polymeric material illustrating a surface of the silver layer according to the example. As is apparent from a comparison of FIGS. 18 and 20, the silver layer has further reduced the pore size of the polymeric material as compared to the pore size of the polymeric material with the copper layer but before the silver layer was formed thereon. Both sides of the polymeric material shown in FIG. 20 are electrically conductive (e.g., have an electrical resistance of less than approximately 10,000 ohms). Moreover, the metallic links formed within the pores by the copper and silver layers of the polymeric material shown in FIG. 20 also provided sufficient electrical conductivity (e.g., an electrical resistance of less than approximately 10,000 ohms) between the opposite sides of the polymeric material. FIG. 20 has a field of view of approximately 13.8 μm.

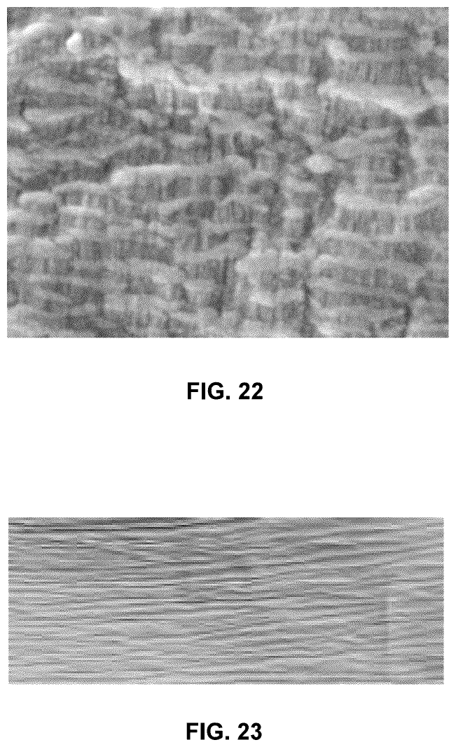

Another experimental example of the polymeric materials disclosed herein will now be described with respect to FIGS. 22 and 23. FIG. 22 illustrates the microstructure of a polymeric material after a vapor deposition process has been performed to deposit approximately 3000 Angstroms of copper onto the sides of a polymer core (e.g., the polymer core shown in FIGS. 16 and 17) and within the pores of the polymer core. FIG. 13 is a plan view of one of the sides of the polymeric material illustrating a surface of the copper layer deposited on the polymer core according to the example. As is apparent from a comparison of FIGS. 16 and 22, the copper layer deposited on the polymer core appears to approximately completely fill the pores of the polymer core. Both sides of the polymeric material shown in FIG. 22 are electrically conductive (e.g., have an electrical resistance of less than approximately 10,000 ohms). Moreover, the metallic links formed within the pores by the approximately 3000 Angstrom copper layer of the polymeric material shown in FIG. 22 also provide sufficient electrical conductivity (e.g., an electrical resistance of less than approximately 10,000 ohms) between the opposite sides of the polymeric material. For example, the electrical resistance of the polymeric material between the opposite sides (i.e., through the thickness of the polymeric material) was measured at approximately 0.0 ohms in this example. FIG. 22 has a field of view of approximately 13.8 μm.

The following clauses describe further aspects:
Clause Set A:
A1. A cable comprising:
an inner conductor;
a dielectric layer extending around the inner conductor; and
a polymeric material extending around the dielectric layer, the polymeric material comprising:
   a polymer core comprising opposite first and second sides, the polymer core comprising a pore that extends through the first and second sides of the polymer core such that the polymer core is porous;
   first and second metallic layers extending on the first and second sides, respectively, of the polymer core; and
   a metallic link extending through the pore from the first metallic layer to the second metallic layer such that the metallic link provides an electrically conductive path between the first and second metallic layers.
A2. The cable of any preceding clause, wherein the pore of the polymer core comprises an interior surface of the polymer core, the metallic link comprising a layer extending on the interior surface.
A3. The cable of any preceding clause, wherein the pore of the polymer core is approximately completely filled by the metallic link.
A4. The cable of any preceding clause, wherein the metallic link defines a plug that substantially fills the pore of the polymer core.
A5. The cable of any preceding clause, wherein the pore of the polymer core is partially filled by the metallic link such that the pore comprises a void.
A6. The cable of any preceding clause, wherein the metallic link conductively bridges the first and second metallic layers together.
A7. The cable of any preceding clause, wherein the metallic link is configured such that the polymeric material is electrically conductive through a thickness of the polymeric material.
A8. The cable of any preceding clause, wherein the polymer core comprises at least one of a tape or a film.
A9. The cable of any preceding clause, wherein at least one of the first metallic layer, the second metallic layer, or the metallic link comprises at least one of copper or silver.
A10. The cable of any preceding clause, wherein the polymeric material is microporous.
A11. The cable of any preceding clause, wherein the polymeric material defines an outer conductor of the cable.
A12. The cable of any preceding clause, further comprising a shield extending around the polymeric material.
A13. The cable of any preceding clause, further comprising a shield extending around the dielectric layer, the polymeric material extending around the shield.
A14. The cable of any preceding clause, further comprising a jacket extending around the polymeric material.
A15. The cable of any preceding clause, wherein the polymeric material is helically-wrapped around the inner conductor.
A16. The cable of any preceding clause, wherein the polymeric material is axially-wrapped around the inner conductor.
A17. The cable of any preceding clause, wherein the inner conductor comprises first and second inner conductors, the dielectric layer comprising a first dielectric layer extending around the first inner conductor and a second dielectric layer extending around the second inner conductor.
A18. The cable of any preceding clause, wherein the cable is a coaxial cable having the inner conductor coaxially aligned with the polymeric material.
Clause set B:
B1. A cable comprising:
an inner conductor;
a dielectric layer extending around the inner conductor; and
an outer conductor extending around the dielectric layer, the outer conductor including a polymeric material comprising:
   a polymer core comprising opposite first and second sides, the polymer core extending a thickness from the first side to the second side, the polymer core being porous with pores that extend through the thickness of the polymer core;
   first and second metallic layers extending on the first and second sides, respectively, of the polymer core; and
   internal metallic structures extending within the pores, wherein the internal metallic structures conductively bridge the first and second metallic layers together.
B2. The cable of any preceding clause, wherein the internal metallic structures connect the first and second metallic layers together such that the internal metallic structures provide electrically conductive paths between the first and second metallic layers.
B3. The cable of any preceding clause, wherein the internal metallic structures are configured such that the polymeric material is electrically conductive through a thickness of the polymeric material.
B4. The cable of any preceding clause, wherein the pores of the polymer core comprise interior surfaces of the polymer core, the internal metallic structures comprising layers extending on the interior surfaces.
B5. The cable of any preceding clause, wherein the pores of the polymer core are approximately completely filled by the internal metallic structures.
B6. The cable of any preceding clause, wherein the internal metallic structures define plugs that substantially fill the pores of the polymer core.
B7. The cable of any preceding clause, wherein the pores of the polymer core are partially filled by the internal metallic structures such that the pores comprise voids.
B8. The cable of any preceding clause, wherein the polymer core comprises at least one of a tape or a film.
B9. The cable of any preceding clause, wherein at least one of the first metallic layer, the second metallic layer, or the internal metallic structures comprises at least one of copper or silver.
B10. The cable of any preceding clause, wherein the polymeric material is microporous.
B11. The cable of any preceding clause, further comprising a shield extending around the outer conductor.
B12. The cable of any preceding clause, further comprising a shield extending around the dielectric layer, the outer conductor extending around the shield.
B13. The cable of any preceding clause, further comprising a jacket extending around the outer conductor.
B14. The cable of any preceding clause, wherein the polymeric material is helically-wrapped around the inner conductor.
B15. The cable of any preceding clause, wherein the polymeric material is axially-wrapped around the inner conductor.
B16. The cable of any preceding clause, wherein the inner conductor comprises first and second inner conductors, the dielectric layer comprising a first dielectric layer extending around the first inner conductor and a second dielectric layer extending around the second inner conductor.
B17. The cable of any preceding clause, wherein the cable is a coaxial cable having the inner conductor coaxially aligned with the outer conductor.
Clause set C:
C1. A cable comprising:
an inner conductor;
a dielectric layer extending around the inner conductor; and
an outer conductor extending around the dielectric layer, the outer conductor including a polymeric material comprising:
   a polymer core comprising opposite first and second sides, the polymer core being porous with pores that extend through the first and second sides of the polymer core;
   first and second metallic layers extending on the first and second sides, respectively, of the polymer core; and
   internal metallic layers extending within the pores and configured such that the polymeric material is electrically conductive through a thickness of the polymeric material.
C2. The cable of any preceding clause, wherein the internal metallic layers conductively bridge the first and second metallic layers together.
C3. The cable of any preceding clause, wherein the internal metallic layers connect the first and second metallic layers together such that the internal metallic layers provide electrically conductive paths between the first and second metallic layers.
C4. The cable of any preceding clause, wherein the polymeric material is microporous.
C5. The cable of any preceding clause, wherein the pores of the polymer core comprise interior surfaces of the polymer core, the internal metallic layers extending on the interior surfaces.
C6. The cable of any preceding clause, wherein the pores of the polymer core are approximately completely filled by the internal metallic layers.
C7. The cable of any preceding clause, wherein the internal metallic layers define plugs that substantially fill the pores of the polymer core.
C8. The cable of any preceding clause, wherein the pores of the polymer core are partially filled by the internal metallic layers such that the pores comprise voids.
C9. The cable of any preceding clause, wherein the polymer core comprises at least one of a tape or a film.
C10. The cable of any preceding clause, wherein at least one of the first metallic layer, the second metallic layer, or the internal metallic layers comprises copper.
C11. The cable of any preceding clause, wherein at least one of the first metallic layer or the second metallic layer comprises silver.
C12. The cable of any preceding clause, further comprising a shield extending around the outer conductor.
C13. The cable of any preceding clause, further comprising a shield extending around the dielectric layer, the outer conductor extending around the shield.
C14. The cable of any preceding clause, further comprising a jacket extending around the outer conductor.
C15. The cable of any preceding clause, wherein the polymeric material is helically-wrapped around the inner conductor.
C16. The cable of any preceding clause, wherein the polymeric material is axially-wrapped around the inner conductor.
C17. The cable of any preceding clause, wherein the inner conductor comprises first and second inner conductors, the dielectric layer comprising a first dielectric layer extending around the first inner conductor and a second dielectric layer extending around the second inner conductor.
C18. The cable of any preceding clause, wherein the cable is a coaxial cable having the inner conductor coaxially aligned with the outer conductor.
Clause set D:
D1. A method for assembling an electrical cable, the method comprising:
applying a dielectric layer around an inner conductor of the cable; and applying a polymeric material around the dielectric layer to form an electrical shielding layer around the inner conductor, wherein the polymeric material comprises a polymer core that is metallized such that the polymeric material is electrically conductive through a thickness of the polymeric material.
D2. The method of any preceding clause, further comprising performing at least one of a heating, soldering, welding, or sintering operation on the electrical cable.
D3. The method of any preceding clause, further comprising terminating the electrical cable to at least one of an electrical connector, a circuit board, another cable, or an electrical conductor.
D4. The method of any preceding clause, further comprising shrinking-wrapping a jacket around the polymeric material.
D5. The method of any preceding clause, wherein applying the polymeric material around the dielectric layer comprises helically-wrapping the polymeric material around the dielectric layer.
D6. The method of any preceding clause, wherein applying the polymeric material around the dielectric layer comprises axially-wrapping the polymeric material around the dielectric layer.
D7. The method of any preceding clause, further comprising applying a shield around the polymeric material.
D8. The method of any preceding clause, further comprising applying a jacket around the polymeric material.

As used herein, a structure, limitation, or element that is “configured to” perform a task or operation is particularly structurally formed, constructed, or adapted in a manner corresponding to the task or operation. For purposes of clarity and the avoidance of doubt, an object that is merely capable of being modified to perform the task or operation is not “configured to” perform the task or operation as used herein.

Any range or value given herein can be extended or altered without losing the effect sought, as will be apparent to the skilled person.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

It will be understood that the benefits and advantages described above can relate to one implementation or can relate to several implementations. The implementations are not limited to those that solve any or all of the stated problems or those that have any or all of the stated benefits and advantages. It will further be understood that reference to ‘an’ item refers to one or more of those items.

The order of execution or performance of the operations in examples of the present application illustrated and described herein is not essential, unless otherwise specified. That is, the operations can be performed in any order, unless otherwise specified, and examples of the application can include additional or fewer operations than those disclosed herein. For example, it is contemplated that executing or performing a particular operation before, contemporaneously with, or after another operation (e.g., different steps, etc.) is within the scope of aspects and implementations of the application.

The term “comprising” is used in this specification to mean including the feature(s) or act(s) followed thereafter, without excluding the presence of one or more additional features or acts. The terms “comprising,” “including,” and “having” are intended to be inclusive and mean that there can be additional elements other than the listed elements. In other words, the use of “including,” “comprising,” “having,” “containing,” “involving,” and variations thereof, is meant to encompass the items listed thereafter and additional items. Accordingly, and for example, unless explicitly stated to the contrary, implementations “comprising” or “having” an element or a plurality of elements having a particular property can include additional elements not having that property. Further, references to “one implementation” or “an implementation” are not intended to be interpreted as excluding the existence of additional implementations that also incorporate the recited features. The term “exemplary” is intended to mean “an example of”.

When introducing elements of aspects of the application or the examples thereof, the articles “a,” “an,” “the,” and “said” are intended to mean that there are one or more of the elements. In other words, the indefinite articles “a”, “an”, “the”, and “said” as used in the specification and in the claims, unless clearly indicated to the contrary, should be understood to mean “at least one.” Accordingly, and for example, as used herein, an element or step recited in the singular and preceded by the word “a” or “an” should be understood as not necessarily excluding the plural of the elements or steps.

The phrase “one or more of the following: A, B, and C” means “at least one of A and/or at least one of B and/or at least one of C.” The phrase “and/or”, as used in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one implementation, to A only (optionally including elements other than B); in another implementation, to B only (optionally including elements other than A); in yet another implementation, to both A and B (optionally including other elements); etc.

As used in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used shall only be interpreted as indicating exclusive alternatives (i.e. “one or the other but not both”) when preceded by terms of exclusivity, such as “either,” “one of” “only one of” or “exactly one of.” “Consisting essentially of,” when used in the claims, shall have its ordinary meaning as used in the field of patent law.

As used in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) can refer, in one implementation, to at least one, optionally including more than one, A, with no B present (and optionally including elements other than B); in another implementation, to at least one, optionally including more than one, B, with no A present (and optionally including elements other than A); in yet another implementation, to at least one, optionally including more than one, A, and at least one, optionally including more than one, B (and optionally including other elements); etc.

Use of ordinal terms such as “first,” “second,” “third,” etc., in the claims to modify a claim element does not by itself connote any priority, precedence, or order of one claim element over another or the temporal order in which acts of a method are performed. Ordinal terms are used merely as labels to distinguish one claim element having a certain name from another element having a same name (but for use of the ordinal term), to distinguish the claim elements.

Having described aspects of the application in detail, it will be apparent that modifications and variations are possible without departing from the scope of aspects of the application as defined in the appended claims. As various changes could be made in the above constructions, products, and methods without departing from the scope of aspects of the application, it is intended that all matter contained in the above description and shown in the accompanying drawings shall be interpreted as illustrative and not in a limiting sense.

It is to be understood that the above description is intended to be illustrative, and not restrictive. For example, the above-described implementations (and/or aspects thereof) can be used in combination with each other. In addition, many modifications can be made to adapt a particular situation or material to the teachings of the various implementations of the application without departing from their scope. While the dimensions and types of materials described herein are intended to define the parameters of the various implementations of the application, the implementations are by no means limiting and are example implementations. Many other implementations will be apparent to those of ordinary skill in the art upon reviewing the above description. The scope of the various implementations of the application should, therefore, be determined with reference to the appended claims, along with the full scope of equivalents to which such claims are entitled. In the appended claims, the terms “including” and “in which” are used as the plain-English equivalents of the respective terms “comprising” and “wherein.” Moreover, the terms “first,” “second,” and “third,” etc. are used merely as labels, and are not intended to impose numerical requirements on their objects. Further, the limitations of the following claims are not written in means-plus-function format and are not intended to be interpreted based on 35 U.S.C. § 112(f), unless and until such claim limitations expressly use the phrase “means for” followed by a statement of function void of further structure.

This written description uses examples to disclose the various implementations of the application, including the best mode, and also to enable any person of ordinary skill in the art to practice the various implementations of the application, including making and using any devices or systems and performing any incorporated methods. The patentable scope of the various implementations of the application is defined by the claims, and can include other examples that occur to those persons of ordinary skill in the art. Such other examples are intended to be within the scope of the claims if the examples have structural elements that do not differ from the literal language of the claims, or if the examples include equivalent structural elements with insubstantial differences from the literal language of the claims.

What is claimed is:

1. A cable comprising:
an inner conductor;
a dielectric layer extending around the inner conductor; and
a polymeric material extending around the dielectric layer, the polymeric material comprising:
a polymer core comprising opposite first and second sides, the polymer core comprising a pore that extends through the first and second sides of the polymer core such that the polymer core is porous;
first and second metallic layers extending on the first and second sides, respectively, of the polymer core; and
a metallic link extending through the pore from the first metallic layer to the second metallic layer such that the metallic link provides an electrically conductive path between the first and second metallic layers.

2. The cable of claim 1, wherein the pore of the polymer core comprises an interior surface of the polymer core, the metallic link comprising a layer extending on the interior surface.

3. The cable of claim 1, wherein the pore of the polymer core is approximately completely filled by the metallic link.

4. The cable of claim 1, wherein the metallic link defines a plug that substantially fills the pore of the polymer core.

5. The cable of claim 1, wherein the pore of the polymer core is partially filled by the metallic link such that the pore comprises a void.

6. The cable of claim 1, wherein the metallic link conductively bridges the first and second metallic layers together.

7. The cable of claim 1, wherein the metallic link is configured such that the polymeric material is electrically conductive through a thickness of the polymeric material.

8. The cable of claim 1, wherein the polymer core comprises at least one of a tape or a film.

9. The cable of claim 1, wherein at least one of the first metallic layer, the second metallic layer, or the metallic link comprises at least one of copper or silver.

10. The cable of claim 1, wherein the polymeric material is microporous.

11. The cable of claim 1, wherein the polymeric material defines an outer conductor of the cable.

12. A cable comprising:
an inner conductor;
a dielectric layer extending around the inner conductor; and
an outer conductor extending around the dielectric layer, the outer conductor including a polymeric material comprising:
a polymer core comprising opposite first and second sides, the polymer core extending a thickness from the first side to the second side, the polymer core being porous with pores that extend through the thickness of the polymer core;
first and second metallic layers extending on the first and second sides, respectively, of the polymer core; and
internal metallic structures extending within the pores, wherein the internal metallic structures conductively bridge the first and second metallic layers together.

13. The cable of claim 12, wherein the internal metallic structures connect the first and second metallic layers together such that the internal metallic structures provide electrically conductive paths between the first and second metallic layers.

14. The cable of claim 12, wherein the internal metallic structures are configured such that the polymeric material is electrically conductive through a thickness of the polymeric material.

15. A cable comprising:
an inner conductor;
a dielectric layer extending around the inner conductor; and
an outer conductor extending around the dielectric layer, the outer conductor including a polymeric material comprising:
a polymer core comprising opposite first and second sides, the polymer core being porous with pores that extend through the first and second sides of the polymer core;
first and second metallic layers extending on the first and second sides, respectively, of the polymer core; and
internal metallic layers extending within the pores and configured such that the polymeric material is electrically conductive through a thickness of the polymeric material.

16. The cable of claim 15, wherein the internal metallic layers conductively bridge the first and second metallic layers together.

17. The cable of claim 15, further comprising a shield extending around the outer conductor.

18. The cable of claim 15, further comprising a shield extending around the dielectric layer, the outer conductor extending around the shield.

19. The cable of claim 15, further comprising a jacket extending around the outer conductor.

20. The cable of claim 15, wherein the inner conductor comprises first and second inner conductors, the dielectric layer comprising a first dielectric layer extending around the first inner conductor and a second dielectric layer extending around the second inner conductor.
